(19) United States
(12) Patent Application Publication
(10) Pub. No.: US 2024/0097090 A1
(43) Pub. Date: Mar. 21, 2024

(54) DISPLAY DEVICE AND METHOD OF MANUFACTURING DISPLAY DEVICE

(71) Applicant: Coretronic Corporation, Hsin-Chu (TW)

(72) Inventors: Ming-Chuan Chih, Hsin-Chu (TW); Wen-Chun Wang, Hsin-Chu (TW); Chun-Chi Hsu, Hsin-Chu (TW); Bo-Chih Pan, Hsin-Chu (TW); Yu-Wei Liang, Hsin-Chu (TW)

(73) Assignee: Coretronic Corporation, Hsin-Chu (TW)

(21) Appl. No.: 18/465,999

(22) Filed: Sep. 13, 2023

(30) Foreign Application Priority Data
Sep. 21, 2022 (CN) 202211156646.X

(51) Int. Cl. H01L 33/62; H01L 23/00; H01L 25/075; H01L 25/13

(52) U.S. Cl. CPC H01L 33/62; H01L 24/19; H01L 24/20; H01L 25/0753; H01L 25/13; H01L 2224/19; H01L 2224/211; H01L 2933/0066

(57) ABSTRACT

A display device including at least two light source modules and a display control substrate is provided. Each of the at least two light source substrates has a first surface and a second surface opposite to each other and includes a plurality of light emitting elements and a plurality of connection pads. The light emitting elements are located on the second surface, and the connection pads are located on the first surface and are electrically connected to the light emitting elements. The display control substrate includes a back plate and a plurality of control elements. The control elements are located on the back plate, part of the control elements are electrically connected to the connection pads to drive and control the light emitting elements, and the second surface of each of the at least two light source substrates forms a part of a display surface of the display device.

### CROSS-REFERENCE TO RELATED APPLICATION

This application claims the priority benefit of China application serial no. 202211156646.X, filed on Sep. 21, 2022. The entirety of the above-mentioned patent application is hereby incorporated by reference herein and made a part of this specification.

### BACKGROUND

### Technical Field

The disclosure relates to an electronic device and a method of manufacturing the electronic device, and more particularly to a display device and a method of manufacturing the display device.

### Description of Related Art

At present, the micro-LED (micro light emitting diode) display on the market mainly transfers a plurality of micro-LED dies onto a circuit substrate through a mass transfer equipment, and then fixes the micro-LED dies to the circuit substrate through a die bonding process. However, the circuit substrate has manufacturing tolerance and the mass transfer equipment has positioning tolerance, and the die bonding process may also have the issue of poor bonding. Taking a 4K UHD (3840×2160) micro-LED display as an example, even if the yield is 99.999%, there will still be 248 bright spots or dark spots, which still exceeds the currently accepted display specifications.

Moreover, when a large-sized micro-LED display is required, small-sized micro-LED displays needs to be spliced to be assembled into the large-sized display. During splicing and assembling, bezels of the small-sized displays cause the overall display region to be discontinuous, resulting in a dark area (dark line) similar to a frame. Furthermore, the size and the contour of the small-sized display is limited by the contour design of the back plate, and the size and the contour of the formed large-sized display is also limited by the size and the contour of the small-sized displays. Unless the design of the back plate is customized, it is impossible to freely manufacture the large-sized display with the required size according to requirements.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the invention was acknowledged by a person of ordinary skill in the art.

### SUMMARY

The disclosure provides a display device and a method of manufacturing the display device, which can easily manufacture a large-sized display device and have good reliability and design freedom.

In order to achieve one, a part, or all of the objectives or other objectives, an embodiment of the disclosure provides a display device. The display device includes at least two light source substrates and a display control substrate. Each of at least two light source substrates has a first surface and a second surface opposite to each other, each of at least two light source substrates includes a plurality of light emitting elements and a plurality of connection pads, the light emitting elements are located on the second surface, and the connection pads are located on the first surface and are electrically connected to the light emitting elements. The display control substrate includes a back plate and a plurality of control elements. The control elements are located on the back plate. Part of the control elements are electrically connected to the connection pads to drive and control the light emitting elements, and the second surface of each of at least two light source modules forms a part of a display surface of the display device.

In order to achieve one, a part, or all of the above objectives or other objectives, an embodiment of the disclosure provides a method of manufacturing a display device. The method of manufacturing the display device includes the following steps. At least two light source modules are formed. Each of the at least two light source modules has a first surface and a second surface opposite to each other, each of the at least two light source modules includes a plurality of light emitting elements and a plurality of connection pads, the light emitting elements are located on the second surface, and the connection pads are located on the first surface and are electrically connected to the light emitting elements. Part of a plurality of control elements on a back plate of a display control substrate is electrically connected to the connection pads, and the second surface of each of the at least two light source modules forms a part of a display surface of the display device.

Based on the above, in the display device of an embodiment of the disclosure, during the process of forming each light source module, since the redistribution layer and the connection pads are sequentially disposed on the light emitting elements, and the connection pads are electrically connected to the contacts of the light emitting elements through the redistribution layer, a die bonding process may be omitted, thereby improving the transfer yield, reducing poor transfer caused by the manufacturing tolerance of a circuit substrate, the warpage of the circuit substrate, the positioning tolerance of a mass transfer equipment, etc., or preventing element damage caused by high-temperature reflow or a post-bonding process. Moreover, the distribution region and the contour on the back plate of the display control substrate of the display device do not need to be matched with the contour of the light source module, the light source module may be freely spliced and installed on the back plate, and the large-sized display device is formed through splicing the small-sized light source modules. In this way, when different light source modules are spliced, the light source modules can have a high degree of freedom in layout. In addition, through controlling the distribution density of the light emitting elements of each light source module in different regions, the resolution of the display device and the difficulty of alignment during manufacturing can be taken into account at the same time.

Other objectives, features and advantages of the disclosure will be further understood from the further technological features disclosed by the embodiments of the disclosure wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic flowchart of a method of manufacturing a display device according to an embodiment of the disclosure.

FIG. 2A, FIG. 3A, FIG. 4A, and FIG. 5A are respectively cross-sectional schematic views of the display device at different steps of the method of manufacturing the display device according to FIG. 1.

FIG. 2B is a schematic flowchart of a method of manufacturing a light source module of FIG. 2A.

FIG. 3B, FIG. 4B, and FIG. 5B are respectively front schematic views according to FIG. 3A, FIG. 4A, and FIG. 5A.

FIG. 5C is an enlarged schematic view of a partial region of FIG. 5A.

FIG. 6A and FIG. 6B are respectively structural schematic views of another display device according to an embodiment of the disclosure.

FIG. 7A to FIG. 7D are respectively front schematic views of another method of manufacturing a display device at different steps according to an embodiment of the disclosure.

FIG. 7E is an enlarged schematic view of a partial region of FIG. 7D.

### DETAILIGHT EMITTING DIODE DESCRIPTION OF DISCLOSED EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

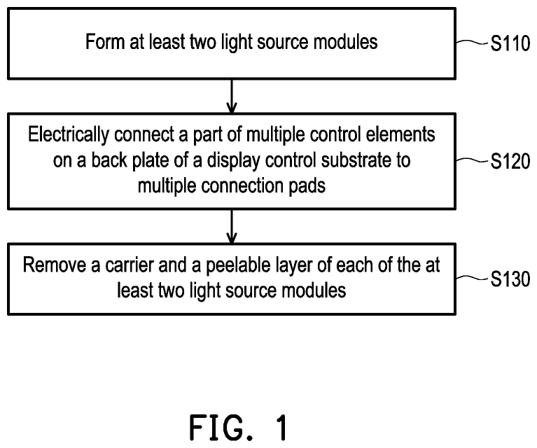

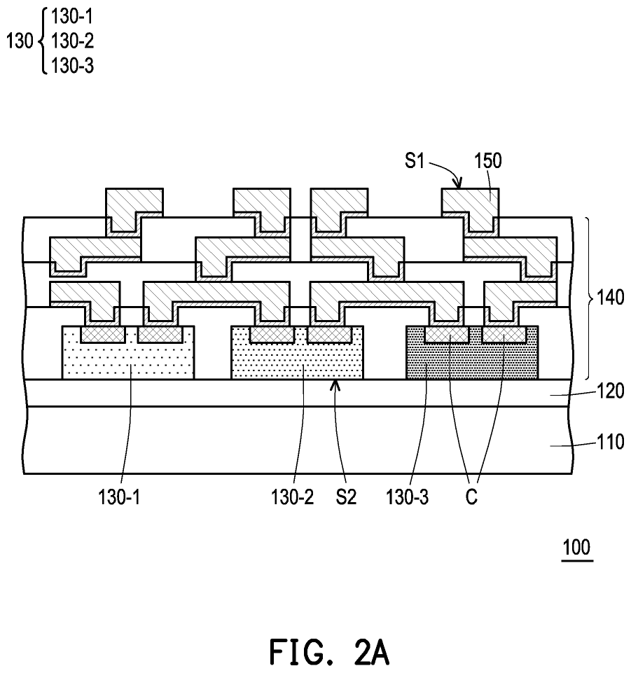

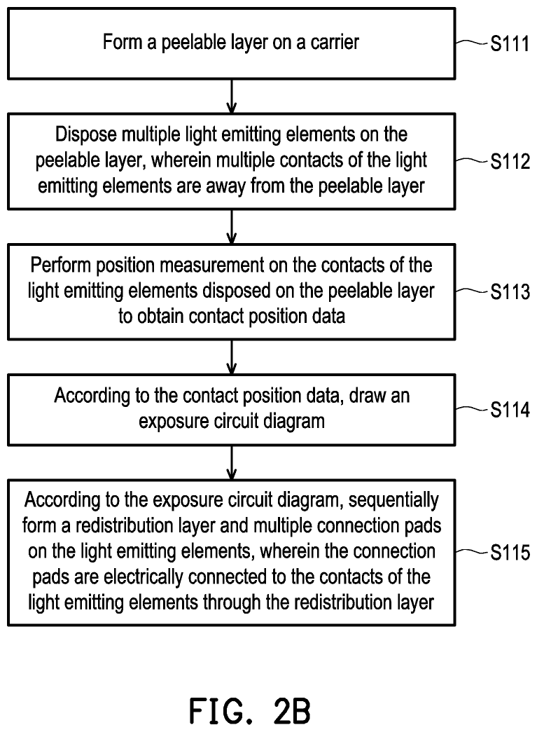

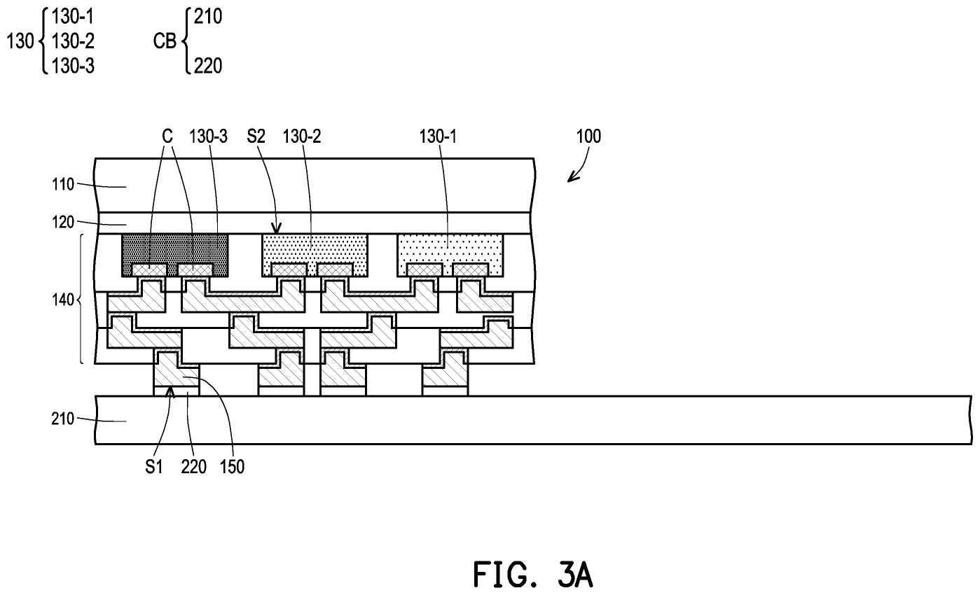

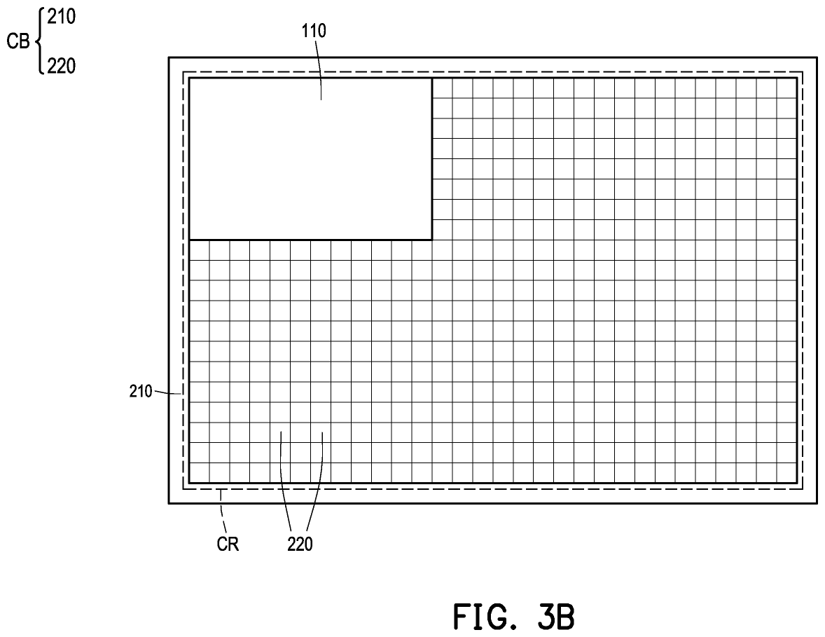

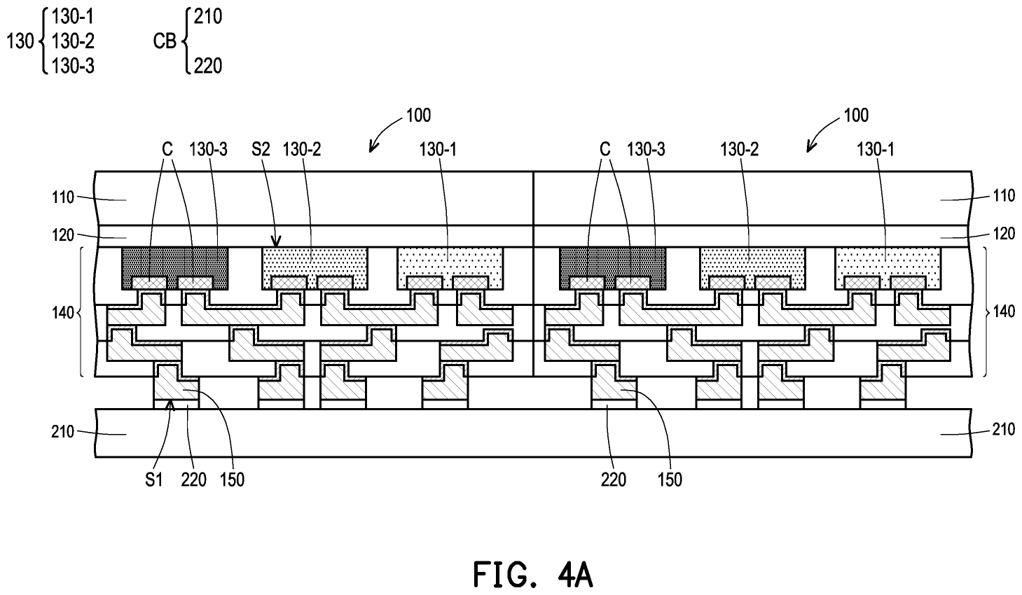

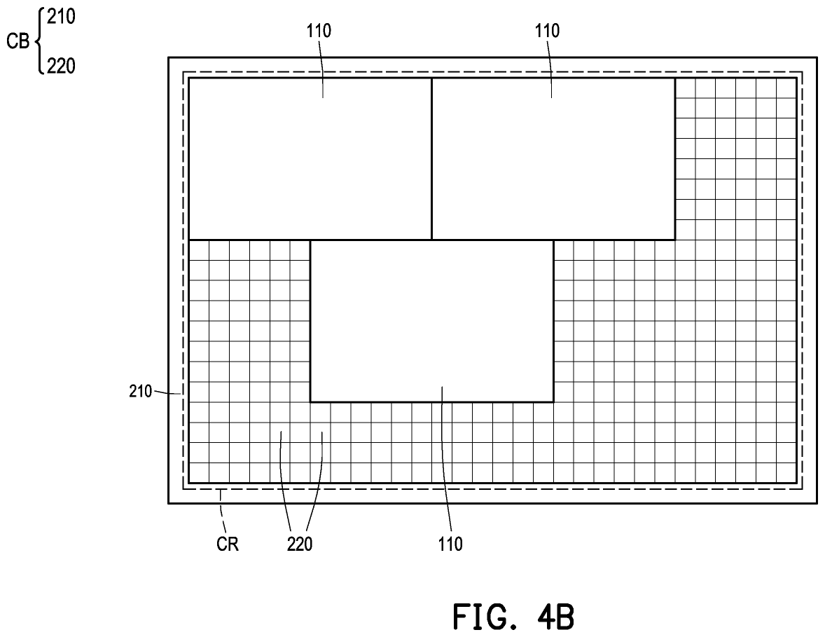

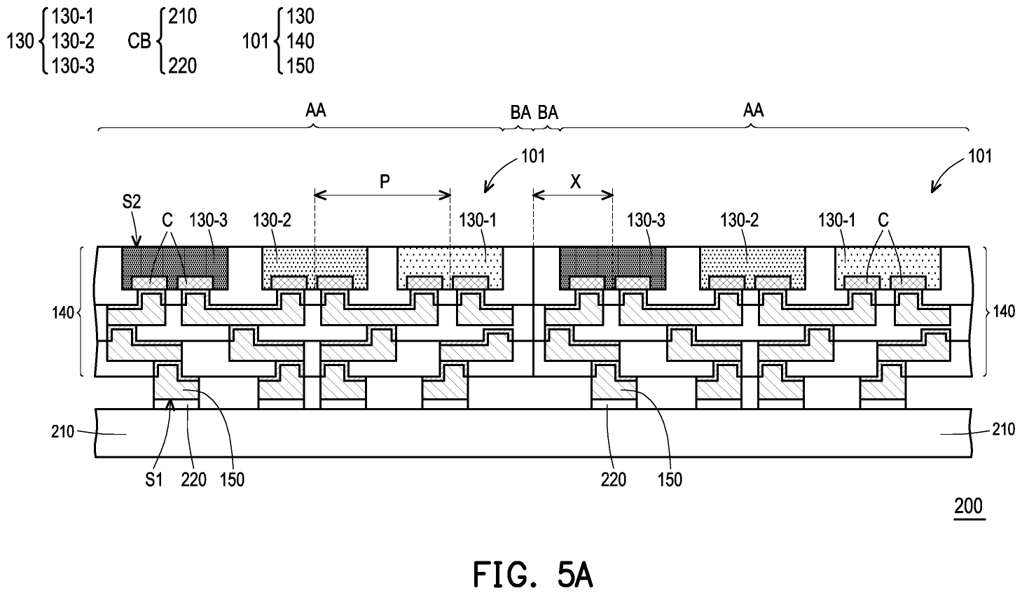

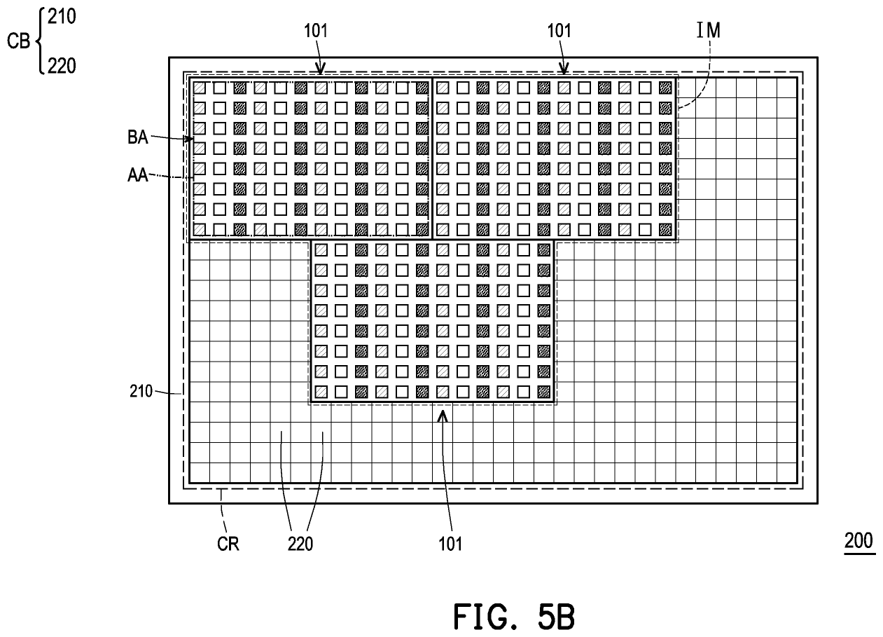

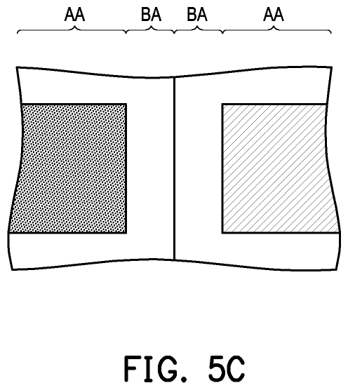

FIG. 1 is a schematic flowchart of a method of manufacturing a display device according to an embodiment of the disclosure. FIG. 2A, FIG. 3A, FIG. 4A, and FIG. 5A are respectively cross-sectional schematic views of the display device at different steps of the method of manufacturing the display device according to FIG. 1. FIG. 2B is a schematic flowchart of a method of manufacturing a light source module of FIG. 2A. FIG. 3B, FIG. 4B, and FIG. 5B are respectively front schematic views according to FIG. 3A, FIG. 4A, and FIG. 5A. FIG. 5C is an enlarged schematic view of a partial region of FIG. 5A. However, it should be understood that FIG. 2A, FIG. 3A, FIG. 4A, and FIG. 5A are only one implementation of the method of manufacturing the display device shown in FIG. 1 and should not limit the scope of the disclosure. Persons skilled in the art can add or subtract one or more steps in FIG. 2A, FIG. 3A, FIG. 4A, and FIG. 5A according to requirements, which are still within the scope of the disclosure.

Please refer to FIG. 1 to FIG. 5C. A method of manufacturing a display device 200 (shown in FIG. 5A) may include forming at least two light source modules 100 (Step S110), and each of the at least two light source modules 100 has a first surface 51 and a second surface S2 opposite to each other, as shown in FIG. 2A, each of the at least two light source modules 100 includes a plurality of light emitting elements 130, a plurality of connection pads 150, a carrier 110, and a peelable layer 120, the light emitting elements 130 are located on the second surface S2, and the connection pads 150 are located on the first surface 51 and are electrically connected to the light emitting elements 130.

For example, as shown in FIG. 2A and FIG. 2B, in the embodiment, a method of forming each of the at least two light source modules 100 (Step S110) includes the following steps. Please refer to FIG. 2A and FIG. 2B. A method of manufacturing the light source module 100 may include forming the peelable layer 120 on the carrier 110 (Step S111). For example, the peelable layer 120 may be formed on the carrier 110 by a coating process, but not limited thereto. The carrier 110 has rigidity to carry an element or a film layer formed thereon. For example, the carrier 110 may be a glass substrate, a plastic substrate, a metal substrate, an alloy substrate, a ceramic substrate, a silicon substrate, other types of substrates, or a combination thereof. In other words, the carrier 110 may be a single-layer plate or a composite plate. The peelable layer 120 may be used to temporarily fix (adhere) the light emitting element 130 (for example, the light emitting elements 130) formed thereon onto the carrier 110, and the peelable layer 120 may lose adhesiveness (adhesiveness decreases) under specific conditions, so that the light emitting element 130 (for example, the light emitting elements 130) formed thereon may be detached from the carrier 110. For example, the peelable layer 120 may include a light release adhesive layer (for example, a UV release adhesive) that loses viscosity when exposed to light, a thermal release adhesive layer that loses viscosity when heated, or a cooling release adhesive layer that loses viscosity when cooled, but not limited thereto.

Please continue to refer to FIG. 2A and FIG. 2B. The method of manufacturing the light source module 100 may further include disposing the light emitting elements 130 on the peelable layer 120, wherein a plurality of contacts C (e.g., electrical pads) of the light emitting elements 130 are away from the peelable layer 120 (Step S112). For example, the light emitting elements 130 may be transferred onto the peelable layer 120 through a plurality of transfer procedures, so that the contacts C of the light emitting elements 130 are away from the peelable layer 120. In other words, after the light emitting elements 130 are transferred onto the peelable layer 120, the contacts C are located on a side of the light emitting elements 130 away from the peelable layer 120. The light emitting elements 130 may include a plurality of micro light emitting diode (micro LED) dies or a plurality of mini light emitting diode (mini LED) dies, but not limited thereto.

In some embodiments, the light emitting elements 130 may include light emitting elements with various colors, such as a plurality of red light emitting elements 130-1 (FIG. 2A only schematically depicts one red light emitting element 130-1), a plurality of green light emitting elements 130-2 (FIG. 2A only schematically depicts one green light emitting element 130-2), and a plurality of blue light emitting elements 130-3 (FIG. 2A only schematically depicts one blue light emitting element 130-3), but not limited thereto. In other embodiments, the light emitting elements 130 may be light emitting elements with the same color. The light emitting elements of each color may be transferred onto the peelable layer 120, for example, via two transfer procedures. For example, the red light emitting elements 130-1 (the green light emitting elements 130-2, or the blue light emitting elements 130-3) may be transferred from a growth substrate (not shown) onto a temporary substrate (not shown) via a first transfer procedure, and then transferred from the temporary substrate onto the peelable layer 120 via a second transfer procedure. Of course, the disclosure does not limit the number of times of transferring the light emitting elements 130 onto the peelable layer 120.

Please continue to refer to FIG. 2A and FIG. 2B. After Step S112, the method of manufacturing the light source module 100 may further include performing position measurement on the contacts C of the light emitting elements 130 disposed on the peelable layer 120 to obtain contacts position data (Step S113). Manners of measuring positions of the contacts C may include contact and non-contact measurement manners. Taking the non-contact measurement manner as an example, images of the light emitting elements 130 may be captured through an image sensor (for example, a camera), and the images captured by the image sensor may be then processed and analyzed by a processor to obtain the contacts position data including the positions of the contacts C. The processor may be coupled to the image sensor via a physical circuit or a wireless network to acquire the images captured by the image sensor. The processor may include a central processing unit (CPU) or a graphics processing unit (GPU), but not limited to. In addition, the processor may be built in a computer CP, a mobile device (not shown), or a cloud (not shown), but not limited thereto.

Next, according to the contacts position data, an exposure circuit diagram is drawn (Step S114). In detail, in a subsequent process, a plurality of exposure steps (or exposure processes) need to be performed on the light emitting elements 130. Before performing the exposure step, the images captured by the image sensor in Step S113 may be used to obtain relevant data of the contacts C (including the contacts position data, contacts size data, contacts pitch data, etc.). The exposure circuit diagram may be drawn according to the relevant data of the contacts C, and the exposure circuit diagram is imported into an exposure machine (not shown) to perform the exposure step. In this way, during the process of transferring the light emitting elements 130, even if the light emitting elements 130 are slightly shifted, a correction effect may be generated when the exposure circuit diagram is drawn. In some embodiments, the exposure machine may be a maskless exposure machine, that is, a maskless lithography process may be used to form relevant circuits or film layers on the light emitting elements 130, but not limited thereto. The maskless exposure machine may include a light source module, a microlens array, a projection lens, etc., but not limited thereto. In some embodiments, the microlens array may be changed to a spatial filter or a digital micromirror device (DMD), but not limited thereto. In other embodiments, the exposure machine may be an exposure machine using a photomask. In some embodiments, after obtaining the contacts position data and before forming the relevant circuits or film layers, the method of manufacturing the light source module 100 may further include performing an electrical test on the light emitting elements 130. If a defective light emitting element 130 is found, the defective light emitting element 130 may be repaired or replaced immediately, which helps to improve the overall yield.

Also, after Step S114, according to the exposure circuit diagram, a redistribution layer 140 and the connection pads 150 may be sequentially formed on the light emitting elements 130, wherein a part of redistribution layer 140 (e.g., insulator) is disposed between the light emitting elements 130, and the connection pads 150 are electrically connected to the contacts C of the light emitting elements 130 through the redistribution layer 140 (Step S115). In this way, the light source module 100 as shown in FIG. 2A may be formed, and since the redistribution layer 140 and the connection pads 150 are sequentially disposed on the light emitting elements 130, and the connection pads 150 are electrically connected to the contacts C of the light emitting elements 130 through the redistribution layer 140, a die bonding process may be omitted, thereby improving the transfer yield, reducing poor transfer caused by the manufacturing tolerance of a circuit substrate, the warpage of the circuit substrate, the positioning tolerance of a mass transfer equipment, etc., or preventing element damage caused by high-temperature reflow or a post-bonding process.

Next, as shown in FIG. 1, FIG. 3A, and FIG. 3B, a method of manufacturing the display device 200 may include electrically connecting part of a plurality of control elements 220 on a back plate 210 of a display control substrate CB to the connection pads 150 (Step S120), so that the control elements 220 may drive and control the light emitting elements 130 of each of the at least two light source modules 100. The control element 220 includes, for example, a control integrated circuit (IC) and a connecting line. For example, in the embodiment, a method of electrically connecting part of the control elements 220 on the back plate 210 of the display control substrate CB to the connection pads 150 may enable each of the at least two light source modules 100 to respectively directly contact and be electrically connected to part of the control elements 220 located in different regions of the back plate 210.

Furthermore, as shown in FIG. 1, FIG. 5A, and FIG. 5B, the method of manufacturing the display device 200 may include removing the carrier 110 and the peelable layer 120 of each of the at least two light source modules 100 (Step S130), so that the second surface S2 of each of the at least two light source modules 100 forms a part of a display surface IM of the display device 200, wherein the light source module 100 in which the carrier 110 and the peelable layer 120 are removed forms a light source substrate 101 (for example, including the light emitting elements 130, the redistribution layer 140, and the connection pads 150). For example, in the embodiment, a method of removing the carrier 110 and the peelable layer 120 of each of the at least two light source modules 100 may include the following steps. As shown in FIG. 4A and FIG. 4B, after respectively electrically connecting each of the at least two light source modules 100 to part of the control elements 220 located in different regions of the back plate 210, as shown in FIG. 5A and FIG. 5B, the carrier 110 and the peelable layer 120 of each of the at least two light source modules 100 are removed at one time, but the disclosure is not limited thereto. In other embodiments, after electrically connecting one of the at least two light source modules 100 to part of the control elements 220 located in one of the regions of the back plate 210, and removing the carrier 110 and the peelable layer 120 of the one of the at least two light source modules 100, the other one of the at least two light source modules 100 is electrically connected to part of the control elements 220 located in another region of the back plate 210.

In this way, the display device 200 including at least two light source substrates 101 and the display control substrate CB as shown in FIG. 5A and FIG. 5B may be formed. Specifically, as shown in FIG. 5A and FIG. 5B, in the embodiment, the display control substrate CB includes the back plate 210 and the control elements 220, and the control elements 220 face the first surface 51, wherein part of the control elements 220 are electrically connected to the connection pads 150 to drive and control the light emitting elements 130. In this way, the second surface S2 of each of the at least two light source substrates 101 forms part of the display surface IM of the display device 200 to be used to directly display a display image. In other words, the first surface 51 of the light source module 100 is an installation surface provided with the connection pads 150 to be used to install and electrically connect the control elements 220, and the second surface S2 is a light exiting surface of the light emitting element 130 and is a part of the display surface IM of the display device 200.

In this way, as shown in FIG. 5A and FIG. 5B, in the embodiment, the distribution region and the contour of the control elements 220 on the back plate 210 of the display control substrate CB do not need to be matched with the contour of the light source substrate 101. The light source modules 100 may be freely spliced and installed at different positions on the back plate 210, and the large-sized display device 200 is formed through splicing the small-sized light source modules 100 (the light source substrates 101). For example, as shown in FIG. 5A and FIG. 5B, the size of the back plate 210 may be determined according to requirements and may also be slightly greater than the size of the display surface IM, and the back plate 210 has an arbitrary contour. An entire region CR in which the control elements 220 are distributed in the back plate 210 may be regarded as a region that may be used to install the light source module 100 (the light source substrate 101). The contour of each light source module 100 may be different from the back plate 210 and may also be different from an overall region in which the control elements 220 are distributed in the back plate 210, as long as the contour of each light source module 100 is less than regions in which the control elements 220 are distributed in the back plate 210, the light source module 100 may be directly installed on the back plate 210. That is, the area of the entire region CR in which the control elements 220 are distributed in the back plate 210 of the display control substrate CB is greater than the area of each light source module 100 (the light source substrate 101). In this way, when different light source modules 100 are spliced, the light source modules 100 can have a high degree of freedom in layout. In addition, the display surface IM of the display device 200 may also be designed according to actual requirements, and a surface of the back plate 210 provided with the control elements 220 may have a region without the light source module 100, so as to further design the contour of the display surface IM without being limited by the contour of the back plate 210.

In addition, through the selection of the material of the back plate 210, the display device 200 may also form different types of display devices. For example, when the back plate 210 is a transparent substrate, the display device 200 may form a transparent display device, when the back plate 210 is a flexible substrate, the display device 200 may form a flexible display device, and when the back plate 210 is a transparent flexible substrate, the display device 200 may form a transparent flexible display device. In this way, the user may select the required display device according to own requirements.

In addition, since the overall region of the display surface IM of the display device 200 is jointly formed by different light source substrates 101, during splicing, the edges of the light source modules 100 need to be aligned, and a spacing distance between the at least two light source substrates 101 needs to be limited, so as to prevent an overly large gap generated by splicing, which affects the quality of the display image. For example, the spacing distance between the light source substrates 101 needs to be less than half of a pitch P of the light emitting elements 130 (e.g., the pitch P between the light emitting elements 130 located next to the spacing distance).

In addition, the pitch P between the light emitting elements 130 affects the resolution of the display device 200, the smaller the pitch P, the higher the distribution density of the light emitting elements 130, and the better the resolution. Therefore, in order to take into account the resolution of the display device 200 and the difficulty of alignment at the same time, in the embodiment, the distribution density of the light emitting elements 130 of each light source substrate 101 may be adjusted according to a configuration region thereof. For example, as shown in FIG. 5A and FIG. 5C, in the embodiment, each light source substrate 101 has an active area AA and a blanking area BA (the edge area of the light source substrate 101) surrounding the active area AA, and the distribution density of the light emitting elements 130 adjacent to the blanking area BA in each light source substrate 101 is less than the distribution density of the light emitting elements 130 away from the blanking area BA. In this way, the distribution density between the light emitting elements 130 in the blanking area BA distributed on the edge of the light source substrate 101 is smaller and the pitch P is larger to facilitate alignment, and the distribution density of the light emitting elements 130 in the active area AA distributed on the edge of the light source substrate 101 is larger to have good resolution.

FIG. 6A and FIG. 6B are respectively structural schematic views of another display device according to an embodiment of the disclosure. A display device 600 of FIG. 6B is similar to the display device 200 of FIG. 5A, with the differences as described below. In the display device 600 of FIG. 6B, a method for electrically connecting part of the control elements 220 to the connection pads 150 are not to enable part of the control elements 220 to directly contact the connection pads 150 of the light source module 100, but as shown in FIG. 6A, part of the control elements 220 are electrically connected to the connection pads 150 of the light source module 100 through a circuit connection element 610. The circuit connection element 610 is a flexible circuit substrate and a part of the circuit connection element 610 may be, as shown in FIG. 6B, disposed on the edge of the light source substrate 101 to be adjacent to the blanking area BA when the light source substrate 101 is disposed on the back plate 210 and the part of the circuit connection element 610 may be disposed in the spacing distance between the light source substrates 101 of the display device 600 (spliced).

In this way, the distribution region and the contour of the control elements 220 on the back plate 210 of the display control substrate CB may not need to be matched with the contour of the light source module 100, the light source module 100 may be freely spliced and installed on the back plate 210, and the large-sized display device 600 is formed through splicing the small-sized light source modules 100, thereby enabling the display device 600 to achieve similar effects and advantages as the display device 200, which will not be repeated here.

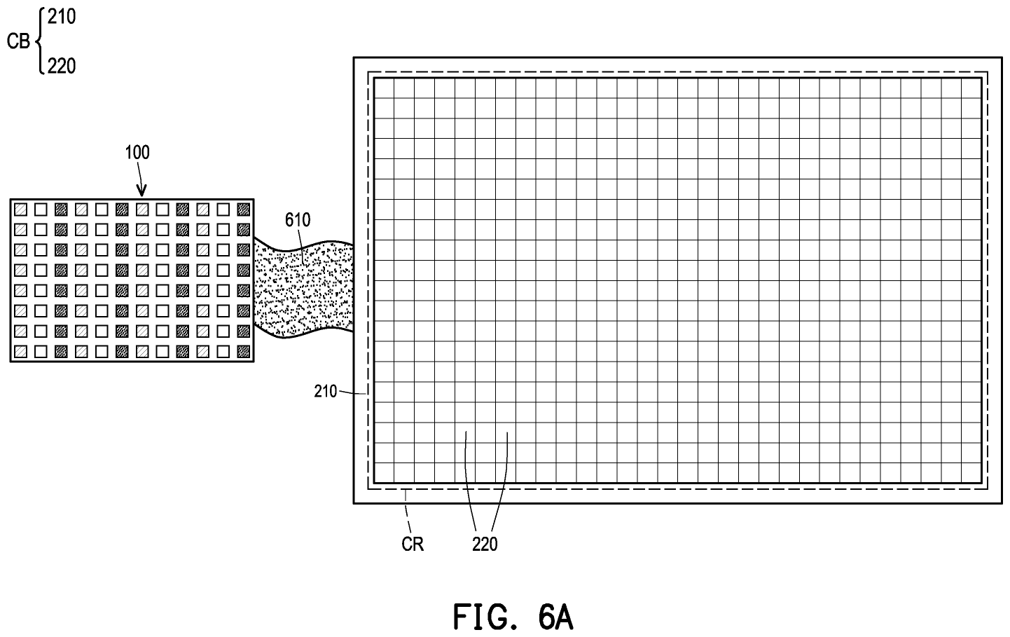

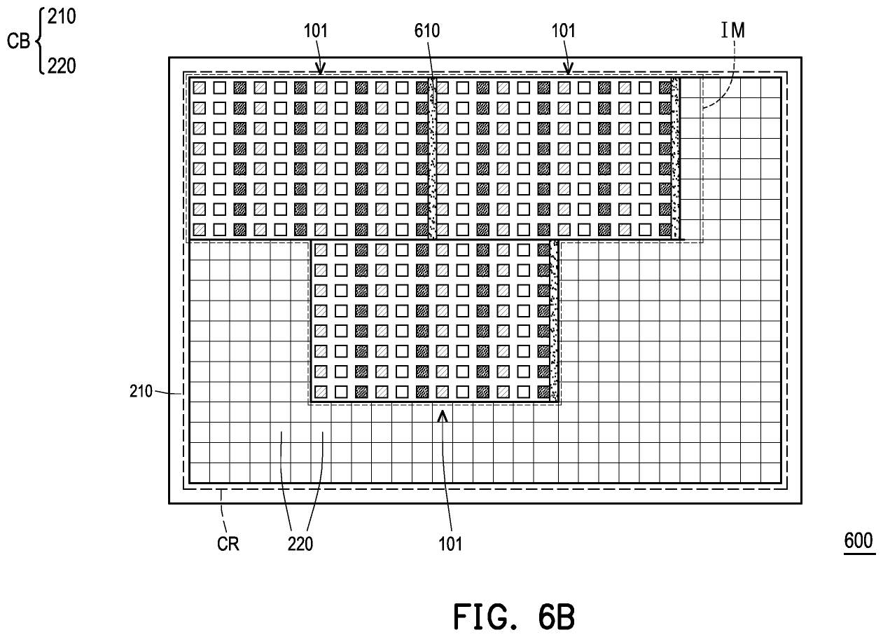

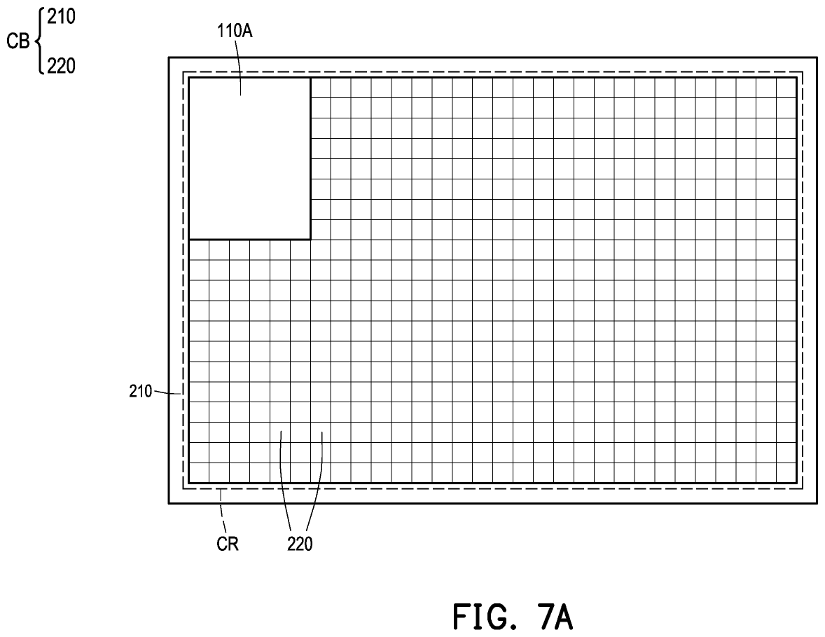

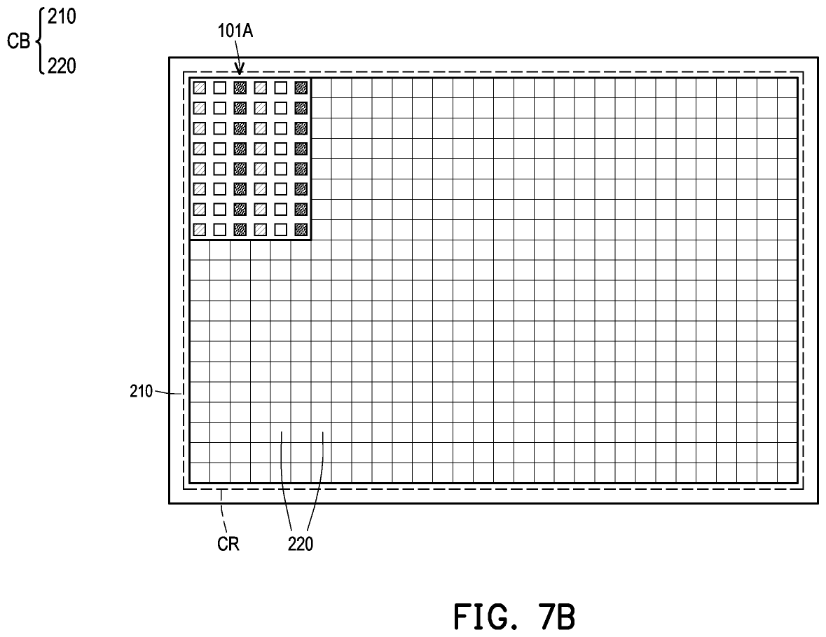

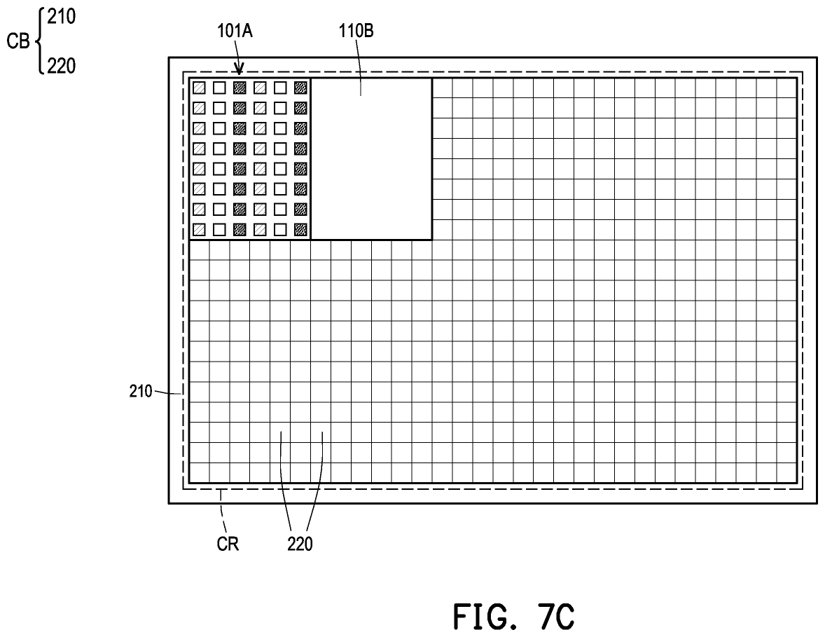

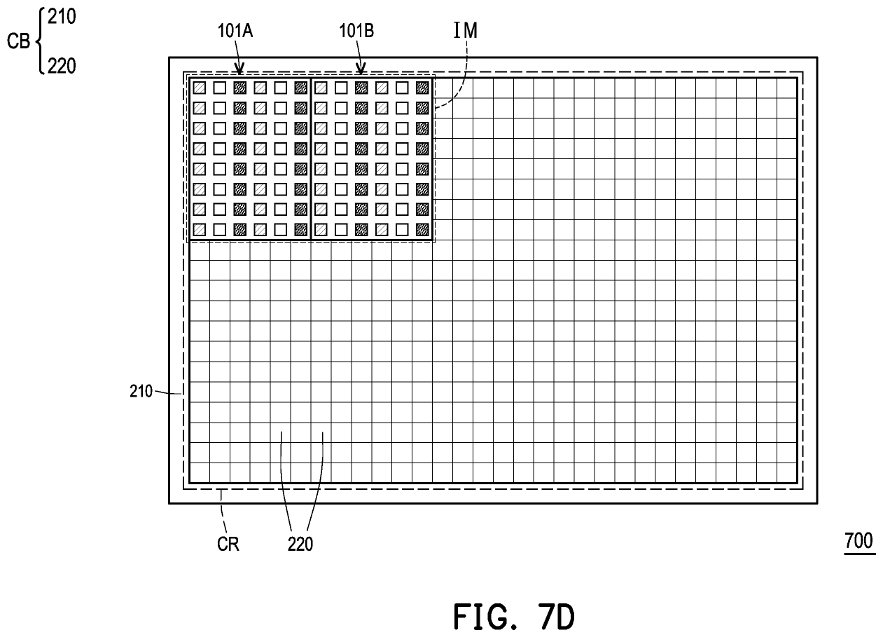

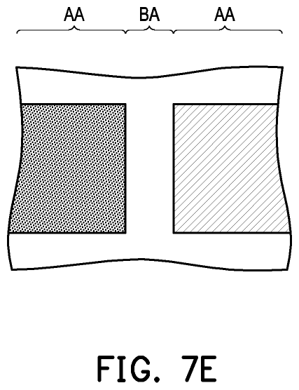

FIG. 7A to FIG. 7D are respectively front schematic views of another method of manufacturing a display device at different steps according to an embodiment of the disclosure. FIG. 7E is an enlarged schematic view of a partial region of FIG. 7D. A display device 700 of FIG. 7D is similar to the display device 200 of FIG. 5A, but a manufacturing method is different, and the difference of the manufacturing method is as follows.

As shown in FIG. 7A, in the embodiment, one of a plurality of light source modules 100A is electrically connected to part of the control elements 220 located in one of the regions of the back plate 210, as shown in FIG. 7B, and the carrier 110 and the peelable layer 120 of the light source module 100A are then removed, as shown in FIG. 7C, so that another light source module 100B is electrically connected to part of the control elements 220 located in another region of the back plate 210. Also, as shown in FIG. 7D, the carrier 110 and the peelable layer 120 of the another light source module 100B are removed.

Furthermore, as shown in FIG. 7E, in the embodiment, the blanking areas BA of two light source substrates 101A and 101B may also overlap with each other, and the blanking area BA of any one of the light source substrates 101A and 101B may not overlap with any light emitting element 130 of the other one of the light source substrates 101A and 101B. In this way, the gap between the active areas AA of the light source substrates 101A and 101B of the display device 700, as shown in FIGS. 7D and 7E (that is, the gap generated by splicing) may be reduced to maintain a good quality of the display image.

In addition, in the embodiment, the distribution region and the contour of the control elements 220 on the back plate 210 of the display control substrate CB of the display device 700 do not need to be matched with the contours of the light source substrates 101A and 101B, the light source substrates 101A and 101B may be freely spliced and installed on the back plate 210, and the large-sized display device 700 is formed through splicing the small-sized light source substrates 101A and 101B, thereby enabling the display device 700 to achieve similar effects and advantages as the display device 200, which will not be repeated here.

In summary, in the display device of an embodiment of the disclosure, during the process of forming each light source module, since the redistribution layer and the connection pads are sequentially disposed on the light emitting elements, and the connection pads are electrically connected to the contacts of the light emitting elements through the redistribution layer, the die bonding process may be omitted, thereby improving the transfer yield, reducing poor transfer caused by the manufacturing tolerance of the circuit substrate, the warpage of the circuit substrate, the positioning tolerance of the mass transfer equipment, etc., or preventing element damage caused by high-temperature reflow or a post-bonding process. Moreover, the distribution region and the contour on the back plate of the display control substrate of the display device do not need to be matched with the contour of the light source module, the light source module may be freely spliced and installed on the back plate, and the large-sized display device is formed through splicing the small-sized light source modules. In this way, when different light source modules are spliced, the light source modules can have a high degree of freedom in layout. In addition, through controlling the distribution density of the light emitting elements of each light source module in different regions, the resolution of the display device and the difficulty of alignment during manufacturing can be taken into account at the same time.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the invention as defined by the following claims. Moreover, no element and component in the disclosure is intended to be dedicated to the public regardless of whether the element or component is explicitly recited in the following claims.

What is claimed is:

1. A display device, comprising:
at least two light source substrates, wherein each of the at least two light source substrates has a first surface and a second surface opposite to each other, each of the at least two light source substrates comprises a plurality of light emitting elements and a plurality of connection pads, the light emitting elements are located on the second surface, and the connection pads are located on the first surface and are electrically connected to the light emitting elements; and
a display control board, comprising:
a back plate; and
a plurality of control elements, located on the back plate, wherein part of the control elements are electrically connected to the connection pads to drive and control the light emitting elements, and the second surface of each of the at least two light source substrates forms a part of a display surface of the display device.

2. The display device according to claim 1, wherein the light emitting elements have a plurality of contacts, each of the at least two light source substrates further comprises a redistribution layer disposed on the light emitting elements and directly connected to the contacts, and the connection pads are electrically connected to the contacts of the light emitting elements through the redistribution layer.

3. The display device according to claim 1, wherein part of the control elements directly contact the connection pads of the light source module.

4. The display device according to claim 1, wherein part of the control elements are electrically connected to the connection pads of the light source substrate through a circuit connection element.

5. The display device according to claim 1, wherein an area of an entire region in which the control elements are distributed in the back plate of the display control substrate is greater than an area of each of the at least two light source substrates.

6. The display device according to claim 1, wherein each of the at least two light source substrates is electrically connected to part of the control elements located in different regions of the back plate, and light exiting surfaces of the at least two light source substrates form different parts of the display surface of the display device, respectively.

7. The display device according to claim 1, wherein there is a spacing distance between the at least two light source substrates, and the spacing distance is less than half of a pitch between the light emitting elements located next to the spacing distance.

8. The display device according to claim 1, wherein each of the at least two light source substrates has an active area and a blanking area surrounding the active area, and a distribution density of the light emitting elements adjacent to the blanking area in each of the at least two light source substrates is less than a distribution density of the light emitting elements away from the blanking area.

9. The display device according to claim 1, wherein each of the at least two light source substrates has an active area and a blanking area surrounding the active area, the blanking area of one of the source substrates and the blanking area of another one of the light source substrates overlap with each other, and the blanking area of any one of the light source substrates does not overlap with any one of the light emitting elements of another one of the light source substrates.

10. A method of manufacturing a display device, comprising:
forming at least two light source modules, wherein each of the at least two light source modules has a first surface and a second surface opposite to each other, each of the at least two light source modules comprises a plurality of light emitting elements and a plurality of connection pads, the light emitting elements are located on the second surface, and the connection pads are located on the first surface and are electrically connected to the light emitting elements;
electrically connecting part of a plurality of control elements on a back plate of a display control substrate to the connection pads, wherein the second surface of each of the at least two light source modules forms a part of a display surface of the display device.

11. The method of manufacturing the display device according to claim 10, wherein an area of an entire region in which the control elements are distributed in the back plate of the display control substrate is greater than an area of each of the at least two light source modules.

12. The method of manufacturing the display device according to claim 10, wherein a method of forming each of the at least two light source modules comprises:
forming a peelable layer on a carrier;
disposing the light emitting elements on the peelable layer, wherein a plurality of contacts of the light emitting elements are away from the peelable layer;
performing position measurement on the contacts of the light emitting elements disposed on the peelable layer to obtain contact position data;
drawing an exposure circuit map according to the contact position information; and
sequentially forming a redistribution layer and the connection pads on the light emitting elements according to the exposure circuit diagram, wherein the connection pads are electrically connected to the contacts of the light emitting elements through the redistribution layer.

13. The method of manufacturing the display device according to claim 10, wherein a method of electrically connecting the part of the control elements on the back plate of the display control substrate to the connection pads comprises:
electrically connecting each of the at least two light source modules to part of the control elements located in different regions of the back plate, wherein light exiting surfaces of the at least two light source modules form different parts of the display surface of the display device, respectively.

14. The method of manufacturing the display device according to claim 13, further comprising:
after electrically connecting each of the at least two light source modules to part of the control elements located in different regions of the back plate, removing the carrier and the peelable layer of each of the at least two light source modules at one time.

15. The method of manufacturing the display device according to claim 14, wherein there is a spacing distance between the at least two light source modules, and the spacing distance is less than half of a pitch between the light emitting elements located next to the spacing distance.

16. The method of manufacturing the display device according to claim 14, wherein each of the at least two light source modules has an active area and a blanking area surrounding the active area, and a distribution density of the light emitting elements adjacent to the blanking area in each of the at least two light source modules is less than a distribution density of the light emitting elements away from the blanking area.

17. The method of manufacturing the display device according to claim 10, further comprising:
after electrically connecting one of the at least two light source modules to part of the control elements located in a region of the back plate, removing the carrier and the peelable layer of the one of the at least two light source modules; and
electrically connecting another one of the at least two light source modules to part of the control elements located in another region of the back plate.

18. The method of manufacturing the display device according to claim 17, wherein each of the at least two light source modules has an active area and a blanking area surrounding the active area, the blanking area of one of the at least two light source modules and the blanking area of another one of the at least two light source modules overlap with each other, and the blanking area of any one of the at least two light source modules does not overlap with any one of the light emitting elements of another one of the other light source modules.
